(19) United States
(12) Patent Application Publication
(10) Pub. No.: US 2013/0337589 A1
(43) Pub. Date: Dec. 19, 2013

(54) FABRICATING METHOD FOR LIGHT EMITTING DIODE

(71) Applicant: Chi Mei Lighting Technology Corp., Tainan (TW)

(72) Inventors: Shin-Jia Chiou, Tainan (TW); Chi-Lung Wu, Tainan (TW); Tzu-Yin Yeh, Tainan (TW); Chun-Te Chiang, Tainan (TW)

(21) Appl. No.: 13/916,719

(22) Filed: Jun. 13, 2013

(30) Foreign Application Priority Data
Jun. 19, 2012 (TW) 101121904

(51) Int. Cl. H01L 33/48

(52) U.S. Cl. CPC H01L 33/48
USPC 438/26

(57) ABSTRACT

A fabricating method for a light emitting diode, includes: providing a bonding substrate; providing an epitaxial structure having an epitaxial substrate and an epitaxial layer, in which the epitaxial layer has a first surface and a second surface opposite to each other, and the epitaxial substrate and the epitaxial layer are combined at the first surface; forming at least one gas discharge channel in the periphery of each single die structure on the epitaxial layer; applying an adhesive on the second surface of the epitaxial layer and the bonding substrate; vaporizing volatile organic gases in the adhesive, and bonding the epitaxial structure and the bonding substrate; removing the epitaxial substrate to expose the first surface of the epitaxial layer; forming electrodes on the exposed first surface of the epitaxial layer; and forming a plurality of light emitting diode dies through cutting along the periphery of each single die structure.

### CROSS-REFERENCE TO RELATED APPLICATIONS

This non-provisional application claims priority under 35 U.S.C. §119(a) on Patent Application No. 101121904 filed in Taiwan, R.O.C. on Jun. 19, 2012, the entire contents of which are hereby incorporated by reference.

Some references, if any, which may include patents, patent applications and various publications, may be cited and discussed in the description of this invention. The citation and/or discussion of such references, if any, is provided merely to clarify the description of the present invention and is not an admission that any such reference is “prior art” to the invention described herein. All references listed, cited and/or discussed in this specification are incorporated herein by reference in their entireties and to the same extent as if each reference was individually incorporated by reference.

### FIELD OF THE INVENTION

The present invention relates generally to a fabricating method for a light emitting diode (LED), and more particularly to a fabricating method for a LED in which volatile organic gases can be effectively discharged in a bonding process.

### BACKGROUND OF THE INVENTION

A LED is a light emitting device fabricated of a semiconductor material and has the advantages such as low power consumption, a long device life, and a high response speed. A LED also has a small volume and can be easily fabricated into a very small or array device. Therefore, with the ongoing development of technologies in recent years, from the applications of a LED as indicator lamps and backlight sources, the applications even extend to the field of lighting.

In conventional fabrication of a LED, on the basis of various application demands, in some applications, an epitaxial structure might need to be bonded to another substrate. In a conventional epitaxial structure, during a glue bonding or spin-on glass (SOG) bonding process, the bonding material needs to be heated to cure. FIG. 1(a) to (e) show a bonding process in which a conventional quaternary epitaxial structure 11 and a bonding substrate 12 are bonded. Referring to FIG. 1(a), firstly a conventional quaternary epitaxial structure 11 and a bonding substrate 12 are provided, and the conventional quaternary epitaxial structure 11 includes an epitaxial substrate 111 and a quaternary epitaxial layer 112. Next, on the conventional quaternary epitaxial structure 11 and the bonding substrate 12, an adhesive 13 is applied on the surface of the quaternary epitaxial layer 112 and the bonding substrate 12 (as shown in FIG. 1(b)). Subsequently, through a heat pre-baking process, volatile organic gas in the adhesive 13 vaporizes (as shown in FIG. 1(c)). Next, through an attachment, heating, and curing process, the quaternary epitaxial structure 11 is bonded to the bonding substrate 12 (as shown in FIG. 1(d)). After accomplishing the bonding of the bonding substrate 12, the epitaxial substrate 111 of the quaternary epitaxial structure 11 is removed. Subsequently, electrodes are then fabricated on the formed structure. Then, a plurality of LED dies is formed through cutting (as shown in FIG. 1(e)). However, as the adhesive 13 is an organic material, organic gases vaporize in the heating process and bubbles are generated (as shown in FIG. 1(d)), which causes undesirable insufficient bonding and adhesive forces between the conventional quaternary epitaxial structure 11 and the bonding substrate 12. In severe cases, the conventional quaternary epitaxial structure 11 is peeled off the bonding substrate 12.

In a conventional method for removing the bubbles is to pre-bake a bonding material first before a bonding process to vaporize most of the organic solvents first, and the operations of attachment and temperature rise are performed to cure the bonding material. However, such a method in which bonding material is pre-baked first still cannot vaporize all the organic solvents, and therefore after bonding, bubbles are still generated between the conventional quaternary epitaxial structure 11 and the bonding substrate 12.

Therefore, a heretofore unaddressed need exists in the art to address the aforementioned deficiencies and inadequacies.

### SUMMARY OF THE INVENTION

In one aspect, the present invention is directed to a fabricating method for a LED, in which volatile organic gases can be effectively discharged in a bonding process.

In one embodiment, a fabricating method for a LED includes: providing a bonding substrate; providing an epitaxial structure having an epitaxial substrate and an epitaxial layer, in which the epitaxial layer has a first surface and a second surface opposite to each other, and the epitaxial substrate and the epitaxial layer are combined at the first surface; forming at least one gas discharge channel in the periphery of each single die structure on the epitaxial layer; applying an adhesive on the second surface of the epitaxial layer and a surface of the bonding substrate; vaporizing volatile organic gases in the adhesive; bonding the epitaxial structure and the bonding substrate; removing the epitaxial substrate to expose the first surface of the epitaxial layer; forming electrodes on the exposed first surface of the epitaxial layer; and forming a plurality of LED dies through cutting along the periphery of each single die structure.

In another embodiment, a fabricating method for a LED includes: providing a bonding substrate; providing an epitaxial structure having an epitaxial substrate and an epitaxial layer, in which the epitaxial layer has a first surface and a second surface opposite to each other, the epitaxial substrate and the epitaxial layer are combined at the first surface, and at least one single die structure is provided on the epitaxial structure; forming at least one gas discharge channel on a surface of the bonding substrate corresponding to the periphery of the single die structure; applying an adhesive on the second surface of the epitaxial layer and the surface of the bonding substrate; vaporizing volatile organic gases in the adhesive; bonding the epitaxial structure and the bonding substrate; removing the epitaxial substrate to expose the first surface of the epitaxial layer; forming electrodes on the exposed first surface of the epitaxial layer; and forming a plurality of LED dies through cutting along the periphery of each single die structure.

In yet another embodiment, a fabricating method for a LED includes: providing a bonding substrate; providing an epitaxial structure having at least one single die structure on the epitaxial structure; forming at least one gas discharge channel at either the bonding substrate or the epitaxial structure, in which the position of the gas discharge channel corresponds to the periphery of each single die structure on the epitaxial structure; applying an adhesive on the epitaxial structure and the bonding substrate; vaporizing volatile organic gases in the adhesive; bonding the epitaxial structure and the bonding substrate; and forming a plurality of LED dies through cutting along the periphery of each single die structure.

These and other aspects of the present invention will become apparent from the following description of the preferred embodiment taken in conjunction with the following drawings, although variations and modifications therein may be effected without departing from the spirit and scope of the novel concepts of the disclosure.

### BRIEF DESCRIPTION OF THE DRAWINGS

The accompanying drawings illustrate one or more embodiments of the invention and together with the written description, serve to explain the principles of the invention. Wherever possible, the same reference numbers are used throughout the drawings to refer to the same or like elements of an embodiment, and wherein:

FIG. 1(a) to (e) show a conventional bonding process in which a quaternary epitaxial structure 11 and a bonding substrate 12 are bonded;

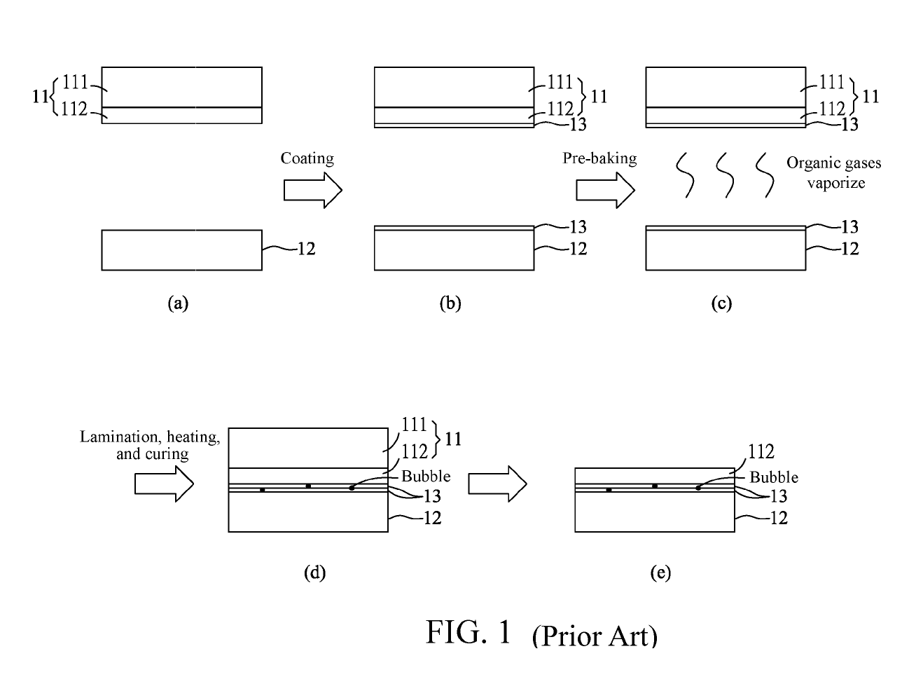

FIG. 2(a) to (e) show a fabricating method for a LED according to a first embodiment of the present invention;

FIG. 3(a) to (f) show a fabricating method for a LED according to a second embodiment of the present invention;

FIG. 4(a) to (e) show a fabricating method for a LED according to a third embodiment of the present invention;

FIG. 5(a) to (f) show a fabricating method for a LED according to a fourth embodiment of the present invention;

FIG. 6 is a schematic view of fabricating an epitaxial structure on an entire wafer according to one embodiment of the present invention; and

FIG. 7 is a schematic view of a cut single LED die structure according to one embodiment of the present invention.

### DETAILED DESCRIPTION OF THE INVENTION

The present invention will now be described more fully hereinafter with reference to the accompanying drawings, in which exemplary embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” or “has” and/or “having” when used in this specification, specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

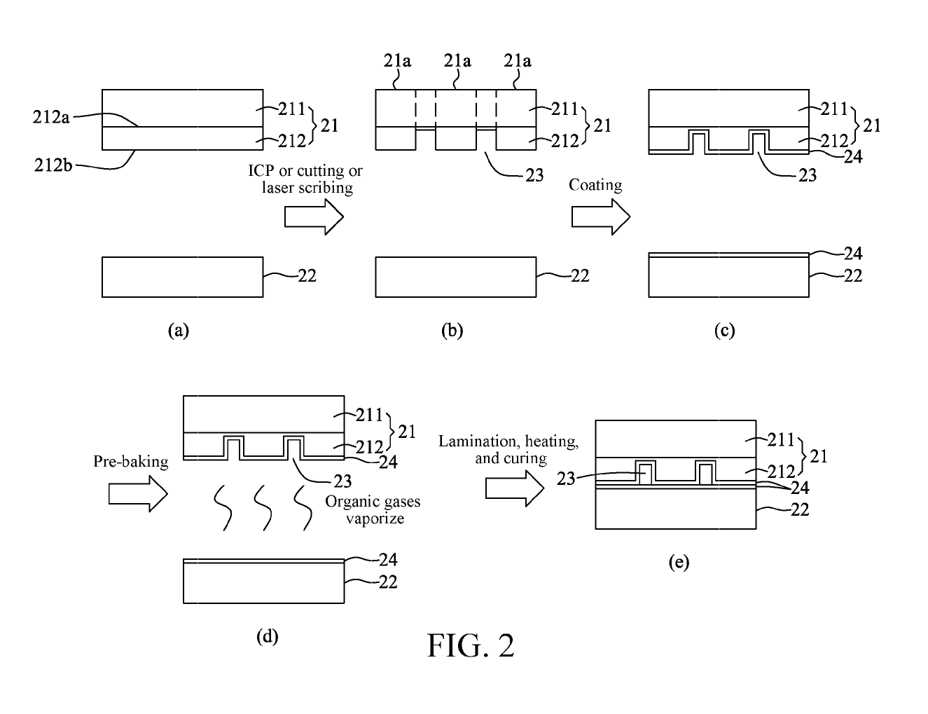

FIG. 2(a) to (e) show a fabricating method for a LED according to a first embodiment of the present invention. Referring to FIG. 2(a), firstly, an epitaxial structure 21 and a bonding substrate 22 are provided. The epitaxial structure 21 includes an epitaxial substrate 211 and an epitaxial layer 212 formed on the epitaxial substrate 211. The epitaxial layer 212 has an n-type semiconductor layer, an active layer, and a p-type semiconductor (not shown). The epitaxial layer 212 has a first surface 212a and a second surface 212b opposite to each other. The epitaxial substrate 211 and the epitaxial layer 212 are combined at the first surface 212a. Further, referring to FIG. 2(b), an inductively coupled plasma (ICP) reactive ion etching process, a mechanical cutting or a laser cutting is applied at the position of a scribe line between single die structures 21a on the epitaxial structure 21, so as to form at least one gas discharge channel 23 on the epitaxial layer 212. The depth of the gas discharge channel 23 is, for example, 5 μm to 15 μm, and preferably 5 μm to 9 μm. In this embodiment, the depth of the gas discharge channel 23 is optimally smaller than the thickness of the epitaxial layer 212. The epitaxial structure 21 is, for example, a quaternary epitaxial structure, in which the epitaxial layer 212 is, for example, an aluminium gallium indium phosphide (AlGaInP) material, whereas the epitaxial substrate 211 is usually formed of gallium arsenide (GaAs). Alternatively, the epitaxial structure 21 is, for example, a gallium nitride (GaN) series epitaxial structure, in which the epitaxial layer 212 is, for example, a GaN material, whereas the epitaxial substrate 211 is a sapphire substrate or a silicon carbide substrate, and the like. Additionally, the material of the bonding substrate 22 includes a gallium nitride, silicon carbide or silicon substrate, and the like. Next, referring to FIG. 2(c), an adhesive 24 is applied on the second surface 212b of the epitaxial layer 212 and the bonding substrate 22. Referring to FIG. 2(d), volatile organic gases of the adhesive 24 vaporize by applying a pre-baking technology (the adhesive 24 is, for example, epoxy). Subsequently, referring to FIG. 2(e), the epitaxial structure 21 and the bonding substrate 22 are bonded by applying an attachment, heating and curing technology. Next, the epitaxial substrate 211 of the epitaxial structure 21 can be removed. After the epitaxial substrate 211 of the epitaxial structure 21 is removed, the first surface 212a of the epitaxial layer 212 is exposed. One or more electrodes are then fabricated on the expose first surface 212a of the epitaxial layer 212. Finally, a plurality of LED dies is formed through cutting along a scribe line.

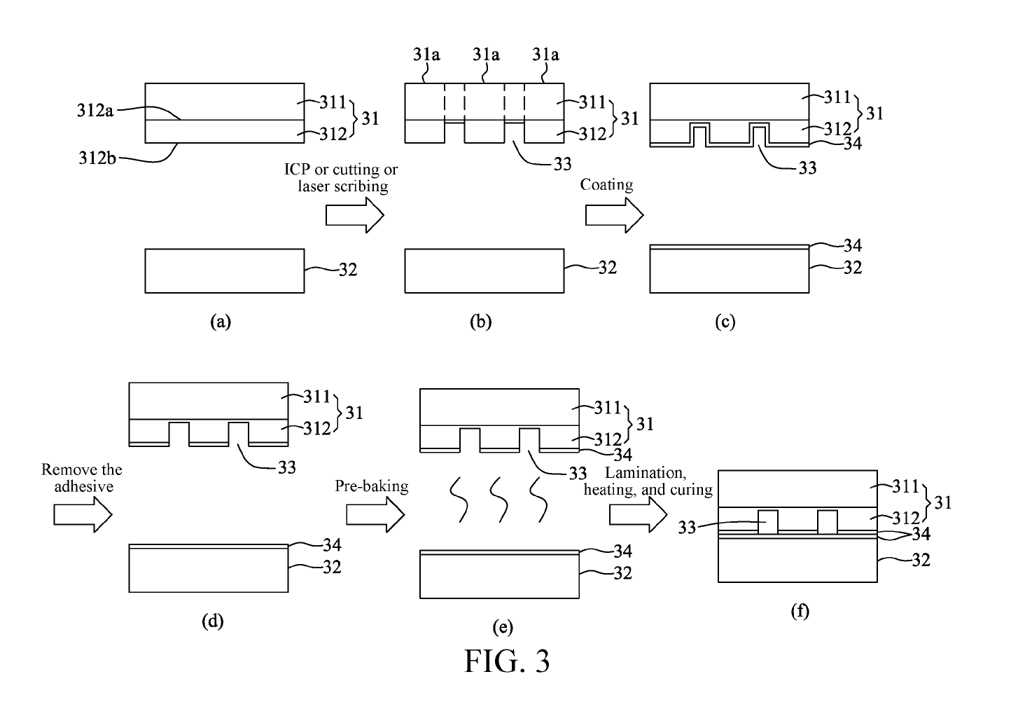

FIG. 3(a) to (f) show a fabricating method for a LED according to a second embodiment of the present invention. This embodiment is similar to the first embodiment, and the difference from the first embodiment lies in that in this embodiment the adhesive on the gas discharge channel is further removed first by applying an etching or photolithography process. The adhesive can be prevented from filling the entire gas discharge channel which makes the gas discharge function ineffective. Therefore, in this embodiment, an adhesive at a channel is removed to make the gas discharge channel through. The detailed fabricating process in this embodiment is as follows. Referring to FIG. 3(a), first, an epitaxial structure 31 and a bonding substrate 32 are provided. The epitaxial structure 31 includes an epitaxial substrate 311 and an epitaxial layer 312 formed on the epitaxial substrate 311. The epitaxial layer 312 has an n-type semiconductor layer, an active layer and a p-type semiconductor (not shown). The epitaxial layer 312 has a first surface 312a and a second surface 312b opposite to each other. The epitaxial substrate 311 and the epitaxial layer 312 are combined at the first surface 312a. In addition, referring to FIG. 3(b), an ICP reactive ion etching process, a mechanical cutting or a laser cutting is applied at the position of a scribe line between single die structures 31a on the epitaxial structure 31, so as to form at least one gas discharge channel 33 on the epitaxial layer 312. The depth of the gas discharge channel 33 is, for example, 5 μm to 15 μm, and preferably 5 μm to 9 μm. In this embodiment, the depth of the gas discharge channel 33 is optimally smaller than the thickness of the epitaxial layer 312. The epitaxial structure 31 is, for example, a quaternary epitaxial structure. The epitaxial layer 312 is, for example, an aluminium gallium indium phosphide (AlGaInP) material, whereas the epitaxial substrate 311 is usually formed of gallium arsenide (GaAs). Alternatively, the epitaxial structure 31 is, for example, a GaN series epitaxial structure, in which the epitaxial layer 312 is, for example, a gallium nitride (GaN) material, whereas the epitaxial substrate 311 is a sapphire substrate or a silicon carbide substrate, and the like. Additionally, the material of the bonding substrate 32 includes a gallium nitride, silicon carbide or silicon substrate, and the like. Next, referring to FIG. 3(c), an adhesive 34 is applied on the second surface 312b of the epitaxial layer 312 of the epitaxial structure 31 and the bonding substrate 32. Then, referring to FIG. 3(d), the adhesive 34 on the gas discharge channel 33 is removed by applying an etching or photolithography process. The method for removing the adhesive 34 on the gas discharge channel 33 includes: (1) if the adhesive 34 is a photosensitive substance, the adhesive 34 of the gas discharge channel 33 can be directly removed with a photographic developer through a photolithography process; (2) if the adhesive 34 is a non-photosensitive substance, the adhesive 34 at the gas discharge channel 33 can be removed through a photolithography and etching process. Subsequently, referring to FIG. 3(e), volatile organic gases on the adhesive 34 vaporize by applying a pre-baking technology, and the adhesive 34 is, for example, epoxy. Subsequently, referring to FIG. 3(f), the epitaxial structure 31 and the bonding substrate 32 are bonded by applying an attachment, heating and curing technology. Next, the epitaxial substrate 311 of the epitaxial structure 31 can be removed. After the epitaxial substrate 311 of the epitaxial structure 31 is removed, the first surface 312a of the epitaxial layer 312 is exposed, and one or more electrodes are then fabricated on the exposed first surface 312a of the epitaxial layer 312. Finally, a plurality of LED dies is formed through cutting along a scribe line.

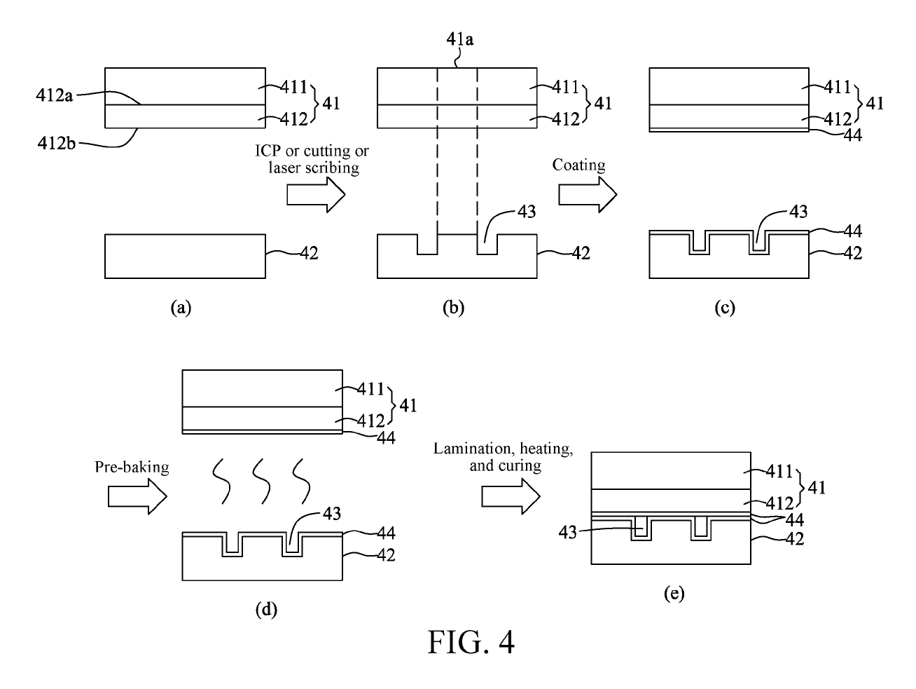

FIG. 4(a) to (e) show a fabricating method for a LED according to a third embodiment of the present invention. Referring to FIG. 4(a), firstly, an epitaxial structure 41 and a bonding substrate 42 are provided. The epitaxial structure 41 includes an epitaxial substrate 411 and an epitaxial layer 412 formed on the epitaxial substrate 411. The epitaxial layer 412 has an n-type semiconductor layer, an active layer, and a p-type semiconductor (not shown). The epitaxial layer 412 has a first surface 412a and a second surface 412b opposite each other. The epitaxial substrate 411 and the epitaxial layer 412 are combined at the first surface 412a. In addition, referring to FIG. 4(b), at least one single die structure 41a is provided on the epitaxial structure 41, and an ICP reactive ion etching process, a mechanical cutting or a laser cutting is applied to form at least one gas discharge channel 43 on the bonding substrate 42 at the position corresponding to a scribe line between single die structures 41a, so as to correspond to the periphery of the single die structure 41a. The depth of the gas discharge channel 43 is, for example, 5 μm to 15 μm, and preferably 5 μm to 9 μm. In this embodiment, the depth of the gas discharge channel 43 is optimally smaller than the thickness of the bonding substrate 42. The epitaxial structure 41 is, for example, a quaternary epitaxial structure, in which the epitaxial layer 412 is, for example, an aluminium gallium indium phosphide (AlGaInP) material, whereas the epitaxial substrate 411 is usually formed of gallium arsenide (GaAs). Alternatively, the epitaxial structure 41 is, for example, a GaN series epitaxial structure, in which the epitaxial layer 412 is, for example, a gallium nitride (GaN) material, whereas the epitaxial substrate 411 is a sapphire substrate or a silicon carbide substrate, and the like. Additionally, the material of the bonding substrate 42 includes gallium nitride, silicon carbide or silicon substrate, and the like. Next, referring to FIG. 4(c), an adhesive 44 is applied on the second surface 412b of the epitaxial layer 412 and the bonding substrate 42, and volatile organic gases on the adhesive 44 vaporize by applying a pre-baking technology, and the adhesive 44 is, for example, epoxy. Subsequently, referring to FIG. 4(e), the epitaxial structure 41 and the bonding substrate 42 are bonded by applying an attachment, heating and curing technology. Next, the epitaxial substrate 411 of the epitaxial structure 41 is removed. After the epitaxial substrate 411 of the epitaxial structure 41 is removed, the first surface 412a of the epitaxial layer 412 is exposed, and one or more electrodes are then fabricated on the exposed first surface 412a of the epitaxial layer 412. Finally, a plurality of LED dies is formed through cutting along a scribe line.

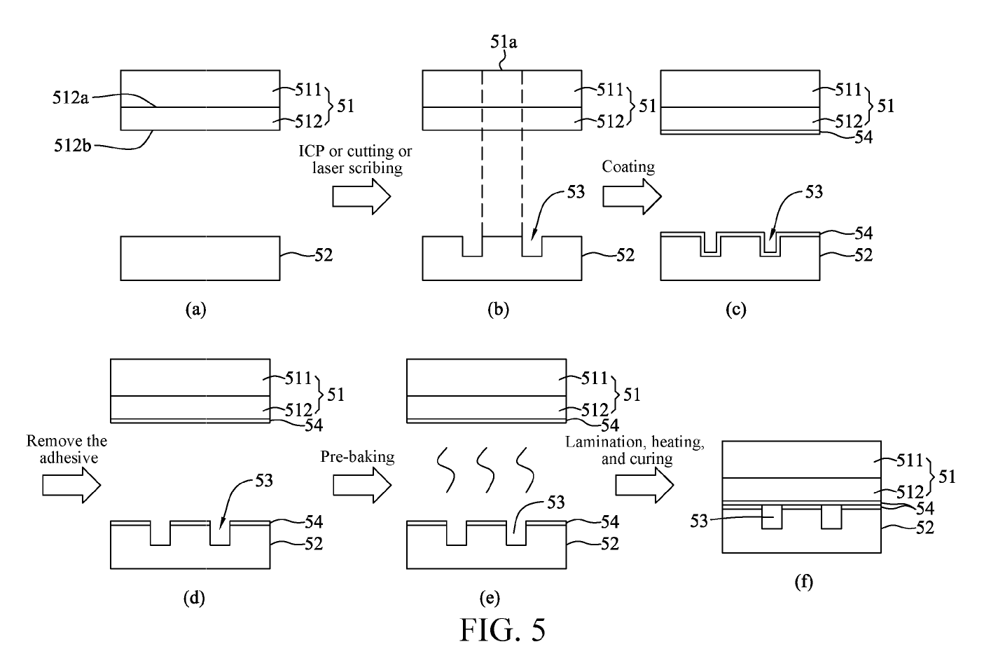

FIG. 5(a) to (f) show a fabricating method for a LED according to a fourth embodiment of the present invention. This embodiment is similar to the third embodiment, and the difference from the third embodiment lies in that in this embodiment, the adhesive on the gas discharge channel is further removed first by applying an etching or photolithography process. The adhesive can be prevented from filling the entire gas discharge channel which makes the gas discharge function ineffective. Therefore, in this embodiment, an adhesive at a channel is removed to make the gas discharge channel through. Referring to FIG. 5(a), an epitaxial structure 51 and a bonding substrate 52 are first provided, and the epitaxial structure 51 includes an epitaxial substrate 511 and an epitaxial layer 512 having an n-type semiconductor layer, an active layer, and a p-type semiconductor (not shown) is formed on the epitaxial substrate 511. The epitaxial layer 512 has a first surface 512a and a second surface 512b opposite to each other. The epitaxial substrate 511 and the epitaxial layer 512 are combined at the first surface 512a. In addition, referring to FIG. 5(b), the epitaxial structure 51 has at least one single die structure 51a, and an ICP reactive ion etching process, a mechanical cutting or a laser cutting is applied to form at least one gas discharge channel 53 on the bonding substrate 52 at the position corresponding to a scribe line between single die structures 51a, so as to correspond to the periphery of the single die structure 51a. The depth of the gas discharge channel 53 is, for example, 5 μm to 15 μm, and preferably 5 μm to 9 μm. In this embodiment, the depth of the gas discharge channel 53 is optimally smaller than the thickness of the bonding substrate 522. The epitaxial structure 51 is, for example, a quaternary epitaxial structure, in which the epitaxial layer 52 is, for example, an aluminium gallium indium phosphide (AlGaInP) material, whereas the epitaxial substrate 511 is usually formed of gallium arsenide (GaAs). Alternatively, the epitaxial structure 51 is, for example, a GaN series epitaxial structure, in which the epitaxial layer 512 is, for example, a gallium nitride (GaN) material, whereas the epitaxial substrate 511 is a sapphire substrate or a silicon carbide substrate, and the like. Additionally, the material of the bonding substrate 52 includes a gallium nitride, silicon carbide or silicon substrate, and the like. Next, referring to FIG. 5(c), an adhesive 54 is applied on the second surface 512b of the epitaxial layer 512 and the bonding substrate 52, and referring to FIG. 5(d), the adhesive 54 on the gas discharge channel 53 is then removed by applying an etching or photolithography process. The method for removing the adhesive 54 on the gas discharge channel 53 includes: (1) if the adhesive 54 is a photosensitive substance, the adhesive 54 of the gas discharge channel 53 can be directly removed with a photographic developer through a photolithography process; (2) if the adhesive 54 is a non-photosensitive substance, the adhesive 54 at the gas discharge channel 53 can be removed through a photolithography and etching process. Next, referring to FIG. 5(e), volatile organic gases on the adhesive 54 vaporize by applying a pre-baking technology, and the adhesive 54 is, for example, epoxy. Subsequently, referring to FIG. 5(f), the epitaxial structure 51 and the bonding substrate 52 are bonded by applying an attachment, heating and curing technology. Next, the epitaxial substrate 511 of the epitaxial structure 51 can be removed. After the epitaxial substrate 511 of the epitaxial structure 51 is removed, the first surface 512a of the epitaxial layer 512 is exposed, and one or more electrodes are then fabricated on the exposed first surface 512a of the epitaxial layer 512. Finally, a plurality of LED dies is formed through cutting along a scribe line.

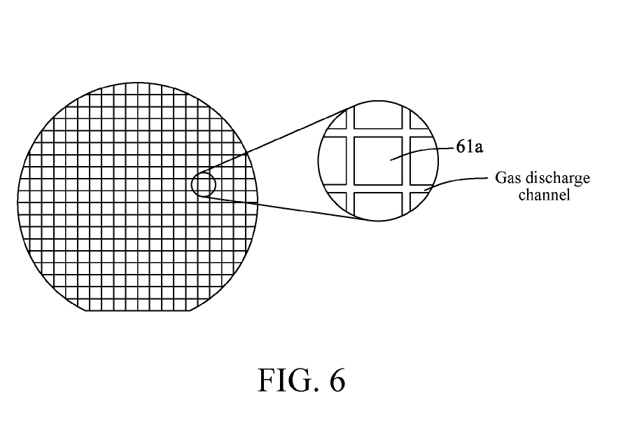

FIG. 6 is a schematic view of fabricating an epitaxial structure on an entire wafer according to one embodiment of the present invention. Referring to FIG. 6, at the boundary of each single die structure 61a (chip boundary) on a wafer, that is, a scribe line between died here, a gas discharge channel is formed through ICP etching, mechanical cutting or laser cutting. An adhesive or bonding material is subsequently applied on the surface of the epitaxial structure and the bonding substrate. Most of the volatile organic gases then vaporize through pre-baking The epitaxial structure and the bonding substrate are subsequently bonded through attachment, heating and curing. Next, the epitaxial substrate of the epitaxial structure can be removed according to demands. During thermal attachment, organic gases can be discharged through the gas discharge channel in the present invention via the edges of the wafer. After the bonding of the bonding substrate and after the epitaxial substrate of the epitaxial structure is removed, one or more electrodes are then fabricated on the formed structure. Finally, a plurality of LED dies is formed through cutting along the periphery of each single die structure (that is, a scribe line).

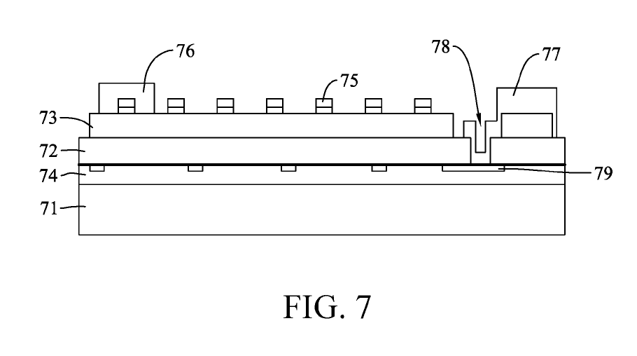

FIG. 7 is a schematic view of a single LED die structure according to one embodiment of the present invention. Referring to FIG. 7, the single LED die structure includes a bonding substrate 71, a P-type semiconductor 72, an N-type semiconductor 73, an active layer (not shown) provided between the P-type semiconductor 72 and the N-type semiconductor 73, and an adhesive 74 that bonds the P-type semiconductor 72 and the bonding substrate 71. A plurality of N-type metal contacts 75 and an N-type bonding pad 76 are provided on the N-type semiconductor 73. A plurality of P-type metal contacts 79 and a P-type bonding pad 77 are provided on the surface of the P-type semiconductor 74. A groove 78 is provided on the P-type semiconductor 72 and the N-type semiconductor 73. The P-type bonding pad 77 is electrically connected to the P-type metal contacts 79 through the groove 78. Through such a design, the P-type bonding pad 77 and the N-type bonding pad 76 are located the same side of the LED die structure to form a horizontal LED structure to facilitate subsequent processes.

The foregoing description of the exemplary embodiments of the invention has been presented only for the purposes of illustration and description and is not intended to be exhaustive or to limit the invention to the precise forms disclosed. Many modifications and variations are possible in light of the above teaching.

The embodiments are chosen and described in order to explain the principles of the invention and their practical application so as to activate others skilled in the art to utilize the invention and various embodiments and with various modifications as are suited to the particular use contemplated. Alternative embodiments will become apparent to those skilled in the art to which the present invention pertains without departing from its spirit and scope. Accordingly, the scope of the present invention is defined by the appended claims rather than the foregoing description and the exemplary embodiments described therein.

What is claimed is:

1. A fabricating method for a light emitting diode (LED), comprising:
providing a bonding substrate;
providing an epitaxial structure having an epitaxial substrate and an epitaxial layer, wherein the epitaxial layer has a first surface and a second surface opposite to each other, and the epitaxial substrate and the epitaxial layer are combined at the first surface;
forming at least one gas discharge channel in the periphery of each single die structure on the epitaxial layer;
applying an adhesive on the second surface of the epitaxial layer and the bonding substrate;
vaporizing volatile organic gases in the adhesive, and bonding the epitaxial structure and the bonding substrate;
removing the epitaxial substrate to expose the first surface of the epitaxial layer;
forming electrodes on the exposed first surface of the epitaxial layer; and
forming a plurality of LED dies through cutting along the periphery of each single die structure.

2. The method of claim 1, further comprising:
removing the adhesive on the gas discharge channel.

3. The method of claim 1, wherein the gas discharge channel is formed between the single die structures on the epitaxial structure by applying an inductively coupled plasma (ICP) reactive ion etching process, a mechanical cutting or a laser cutting.

4. The method of claim 1, wherein the epitaxial structure is a quaternary epitaxial structure, and the quaternary epitaxial structure is formed of aluminium gallium indium phosphide (AlGaInP).

5. The method of claim 1, wherein the adhesive is epoxy.

6. A fabricating method for a light emitting diode (LED), comprising:
providing a bonding substrate;
providing an epitaxial structure having an epitaxial substrate and an epitaxial layer, wherein the epitaxial layer has a first surface and a second surface opposite each other, the epitaxial substrate and the epitaxial layer are combined at the first surface, and at least one single die structure is provided on the epitaxial structure;
forming at least one gas discharge channel on the bonding substrate corresponding to the periphery of the single die structure;
applying an adhesive on the second surface of the epitaxial layer and the bonding substrate;
vaporizing volatile organic gases in the adhesive;
bonding the epitaxial structure and the bonding substrate;
removing the epitaxial substrate to expose the first surface of the epitaxial layer;
forming electrodes on the exposed first surface of the epitaxial layer; and
forming a plurality of LED dies through cutting along the periphery of each single die structure.

7. The method of claim 6, further comprising:
removing the adhesive on the gas discharge channel.

8. The method of claim 7, wherein if the adhesive is a non-photosensitive substance, the adhesive on the gas discharge channel is removed by applying a photolithography and etching process.

9. The method of claim 7, wherein if the adhesive is a photosensitive substance, the adhesive on the gas discharge channel is removed with a photographic developer by applying a photolithography process.

10. The method of claim 6, wherein the epitaxial structure is a quaternary epitaxial structure, and the quaternary epitaxial structure is formed of aluminium gallium indium phosphide (AlGaInP).

11. The method of claim 6, wherein the material of the bonding substrate comprises gallium nitride, silicon carbide or silicon substrate.

12. A fabricating method for a light emitting diode (LED), comprising:
providing a bonding substrate;
providing an epitaxial structure having at least one single die structure on the epitaxial structure;
forming at least one gas discharge channel at either the bonding substrate or the epitaxial structure, wherein the position of the gas discharge channel corresponds to the periphery of each single die structure on the epitaxial structure;
applying an adhesive on the epitaxial structure and the bonding substrate;
vaporizing volatile organic gases in the adhesive;
bonding the epitaxial structure and the bonding substrate; and
forming a plurality of LED dies through cutting along the periphery of each single die structure.

13. The method of claim 12, wherein the gas discharge channel is provided at the bonding substrate.

14. The method of claim 13, wherein the depth of the gas discharge channel is smaller than the thickness of the bonding substrate.

15. The method of claim 12, wherein the gas discharge channel is provided at the epitaxial structure.

16. The method of claim 15, wherein the epitaxial structure comprises an epitaxial substrate and an epitaxial layer, and the depth of the gas discharge channel is smaller than the thickness of the epitaxial layer.

17. The method of claim 12, wherein the depth of the gas discharge channel is 5 μm to 15 μm.

18. The method of claim 17, wherein the depth of the gas discharge channel is 5 μm to 9 μm.
